(19) United States
(12) Patent Application Publication
(10) Pub. No.: US 2010/0181100 A1
(43) Pub. Date: Jul. 22, 2010

(54) COPPER CIRCUIT WIRING BOARD AND METHOD FOR MANUFACTURING THE SAME

(75) Inventors: Hiroshi NAKANO, Tokai (JP); Hitoshi SUZUKI, Hitachi (JP); Toshio HABA, Tokai (JP); Haruo AKAHOSHI, Hitachi (JP); Hiroshi YOSHIDA, Mito (JP); Akira CHINDA, Hitachi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Cable, Ltd.

(21) Appl. No.: 12/690,949

(22) Filed: Jan. 21, 2010

(30) Foreign Application Priority Data
Jan. 22, 2009 (JP) 2009-011735

(51) Int. Cl. H05K 1/09; H05K 1/00; H05K 1/11; B05D 5/12; C25D 5/02

(52) U.S. Cl. 174/251; 174/250; 174/257; 174/261; 427/98.5; 205/125

(57) ABSTRACT

A copper wiring board having fine wiring, and a method for manufacturing the same are provided. The copper wiring board of the present invention is a wiring board comprising an insulating substrate, a plurality of wire trenches formed in the insulating substrate, and wires filled in the wire trenches, wherein when any two of the wires are selected, and cross sections are taken perpendicular to a direction of current flow in the wires, a wire width in one wire cross section is narrower than a wire width in the other wire cross section, and a wire thickness in the one wire cross section is thicker than a wire thickness in the other wire cross section.

### BACKGROUND OF THE INVENTION

1. Field of the Invention

The present invention relates to a copper circuit wiring board, in which fine wiring is provided, preferably used for an electronic component, and a method for manufacturing the same.

2. Background Art

In recent years, as typified by cellular phones, for example, as the smaller size and higher functionality of electronic equipment are achieved, the smaller size of mounted electronic components themselves has been promoted, and with this, an improvement in wiring density on the circuit board has been aimed at. To improve wiring density on the circuit board, multilayered wiring and finer wiring have been made toward a shape that allows higher density mounting.

A general method for manufacturing a wiring board having copper wiring and interlayer connection vias on a circuit board is photolithography. Methods for forming wiring or interlayer connection vias using this photolithography are broadly divided into two groups. One is a subtractive method, and the other is an additive method. The subtractive method is a method in which an etching resist film is formed on a copper film formed on a substrate, and copper other than portions, which are wiring and vias, is etched to form a pattern. The additive method is a method in which portions on a substrate other than portions, which are wiring and vias, are covered with a plating resist film, and only the portions, which are wiring and vias, are plated to form a pattern.

But, there are problems when copper wiring having a wire pitch of 20 μm or less is formed by these methods. The problem of the subtractive method is that the wire cross section shape becomes trapezoidal by side etching in the step of etching copper. This problem is noticeable when a thicker copper film is etched for wires having a large aspect ratio, that is, finer wires. On the other hand, the problem of a semi-additive method is that the removal of the resist between fine wires is difficult. Also, there is a problem that when an alloy, such as nickel, is used as a seed layer in a COF (Chip On Film) and the like, the removal of this seed layer is difficult.

As measures for improving the above problems, for example, JP Patent Publication (Kokai) No. 2006-41036 A, JP Patent Publication (Kokai) No. 2005-57277 A, JP Patent Publication (Kokai) No. 2006-249478 A, and JP Patent Publication (Kokai) No. 2006-303438 A propose methods in which the process of forming concave portions in a substrate is introduced, and then, the concave portions are filled by plating, and the like. In these methods, first, concave portions, such as wire trenches and vias, are formed in a substrate, a seed layer, which is a feed layer for the deposition of copper plating by post-treatment, is formed on the entire substrate surface, and copper is embedded on the seed layer in the concave portions by copper electroplating. In these methods, the wire shape is determined by the shape of the resist, and therefore, the control of the wire shape is easy. Also, the copper wiring is embedded, and therefore, it is not removed more than necessary by etching, and the removal of the resist film and the seed layer is unnecessary. These methods are used as damascene methods in forming the copper wiring of an LSI.

As disclosed in JP Patent Publication (Kokai) No. 2006-41036 A and JP Patent Publication (Kokai) No. 2005-57277 A, in the case where the damascene method is used in forming the copper wiring of an LSI, over plating occurs in fine wire portions, and under plating occurs in wide-width wire portions, when wide-width wires and narrow-width wires are mixed. Therefore, it is necessary to sufficiently perform plating to sufficiently embed copper in the wide-width portions, and therefore, it is necessary to polish extra copper overflowing the narrow-width portions, and so on. In other words, in the conventional methods in which copper is embedded in concave portions by copper electroplating, there is a problem that effort and time are required to remove extra copper deposited on portions other than the concave portions. Also, in the case of a process using a Si wafer, for an LSI and the like, as in JP Patent Publication (Kokai) No. 2006-41036 A and JP Patent Publication (Kokai) No. 2005-57277 A, the substrate is very flat, and therefore, it is possible to perform polishing by CMP (Chemical Mechanical Polishing) and the like so that the height of wires is a designed value. But, it is very difficult to apply the damascene method to polish a substrate having gentle unevenness and a large area, such as a printed board, with uniform thickness. Further, there is also a problem that it is difficult to avoid flaws due to polishing scraps because the gauge of the wires and the type of the insulating material are largely different.

Also, as disclosed in JP Patent Publication (Kokai) No. 2006-249478 A and JP Patent Publication (Kokai) No. 2006-303438 A, in the damascene method, the feed layer for electroplating is formed on the entire substrate surface, and therefore, plating is uniformly deposited on the entire substrate surface, and there is a limit to thinning the plating film thickness other than in the concave portions. Therefore, there is a problem that extra time is required for chemical etching, electrolytic etching, and the like to thin or remove extra copper deposited on portions other than the concave portions. Further, the volume of the concave portion is different for each wire width, and therefore, when plating treatment is simultaneously performed on the wide-width portions and the narrow-width portions, of course, the filling rate of plating deposited in the trenches is different. For example, the filling rate is low in the wide-width portions, and on the contrary, the filling rate is high in the narrow-width portions. Therefore, when it is attempted to fill, based on the wide-width portions, the problem arises that time is required for chemical etching, electrolytic etching, and the like to thin or remove extra copper deposited on portions other than the wide-width portions. Therefore, when the filling of the wide-width wires with plating is insufficient, concave portions are formed in part of the wide-width wires, and therefore, there is a problem that even if it is attempted to form vias in the lower layer after an insulating layer is placed on the plating layer, the insulating layer remains, and the metal portion is not easily exposed. Also, when an insulating film is formed on the upper portion of the wiring, the insulating film cannot sufficiently cover the metal layer, and voids may be formed, if noticeable unevenness is present in the metal layer.

Further, when pads for mounting electronic devices are formed in the same plane as the wiring layer, the connection of electronic components is difficult unless the pad portions are formed convexly from the insulating film. But in conventional methods, it is difficult to fill a large pattern, such as pads.

The present invention has been made in view of such circumstances, and it is an object of the present invention to provide a copper wiring board in which a wiring pattern corresponding to higher density wiring and finer wiring is precisely formed at low cost, and a method for forming the same.

### SUMMARY OF THE INVENTION

The wiring board of the present invention is a copper wiring board comprising at least an insulating substrate, and patterned concave portions (wire trenches), in which wires are filled, in a surface of the insulating substrate, wherein when a fine wire portion and a wide-width wire are mixed, the depth of the concave portions is formed so that the wide-width portion is thinner, and a first metal layer, which is a barrier layer, and a second metal layer, which is wiring, are provided in the concave portions.

Specifically, the wiring board of the present invention is a wiring board comprising an insulating substrate, a plurality of wire trenches formed in the insulating substrate, and wires filled in the wire trenches, wherein when any two of the wires are selected, and cross sections are taken perpendicular to a direction of current flow in the wires, a wire width in one wire cross section is narrower than a wire width in the other wire cross section, and a wire thickness in the one wire cross section is thicker than a wire thickness in the other wire cross section. In other words, wires filled in a plurality of wire trenches having different wire widths and wire depths are provided in the insulating substrate, and when the wire filled in a wire trench having any wire width and wire depth, among the wires, is a reference wire, in the wires, the wire depth of the wire having a narrower wire width than the reference wire is deeper than the wire depth of the reference wire.

Also, the wiring board of the present invention is a wiring board comprising an insulating substrate, a wire trench formed in the insulating substrate, and a wire filled in the wire trench, wherein when any two points of the wire are selected, and cross sections are taken perpendicular to a direction of current flow in the wire, a wire width in one wire cross section is narrower than a wire width in the other wire cross section, and a wire thickness in the one wire cross section is thicker than a wire thickness in the other wire cross section. In other words, a wire filled in a wire trench having continuously changing wire width and wire depth is provided in the insulating substrate, and when the wire filling with a wire width and a wire depth, when a cross section of the wire trench is taken in any place of the wire in a direction perpendicular to the insulating substrate, is a reference wire, in the wire, the wire depth of the wire continuously changing to be thicker from the reference wire as a starting point becomes continuously shallower, and the wire depth of the wire continuously changing to be thinner becomes continuously deeper.

Also, a method for manufacturing a wiring board according to the present invention is a method for manufacturing a wiring board, comprising at least a step A of forming a plurality of wire trenches in an insulating substrate; and a step B of filling the formed wire trenches with a first metal layer, which is a base metal film, wherein in the step A, the plurality of wire trenches are formed to comprise wires in which, when any two of the wires are selected, and cross sections are taken perpendicular to a direction of current flow in the wires, a wire width in one wire cross section is narrower than a wire width in the other wire cross section, and a wire thickness in the one wire cross section is thicker than a wire thickness in the other wire cross section.

Also, a method for manufacturing a wiring board according to the present invention is a method for manufacturing a wiring board, comprising at least a step A of forming a plurality of wire trenches in an insulating substrate; a step B of molding a pad trench in part of the wire trenches; and a step C of filling the formed wire trenches and pad trench with a first metal layer, which is a base metal film, wherein in the step B, the pad trench is formed so that when a cross section is taken perpendicular to a direction of current flow in the wire, a depth of the pad trench is shallower than a wire depth in the wire cross section.

According to the present invention, it is possible to form at low cost a uniform wiring pattern that provides no wiring unevenness or voids even if a fine wire and a wide-width wire are mixed at high density. Also, it is possible to provide a copper wiring board having high reliability, with a structure having a barrier film in wiring.

### BRIEF DESCRIPTION OF THE DRAWINGS

FIG. 1 shows the configuration of a copper wiring board.

FIGS. 2(A) to 2(E) show a process for manufacturing a copper wiring board.

FIGS. 3(A) to 3(E) show a process for manufacturing a copper wiring board.

FIGS. 4(A) to 4(F) show a process for manufacturing a copper wiring board.

FIG. 5 shows a cross-sectional structure of a copper wiring board.

FIG. 6 shows the electrochemical properties of an electroplating solution.

FIGS. 7(A) to 7(D) show a pattern and cross-sectional structure of a copper wiring board.

FIG. 8 shows a cross-sectional structure of a copper wiring board.

FIGS. 9(A) and 9(B) show a pattern and cross-sectional structure of a copper wiring board.

FIG. 10 shows a cross-sectional structure of a copper wiring board.

FIGS. 11(A) and 11(B) show one example of the relationship between wire width and wire trench depth.

### DETAILED DESCRIPTION OF THE PREFERRED EMBODIMENTS

The copper wiring board of the present invention is a copper wiring board comprising at least an insulating substrate, and patterned concave portions, in which wires are filled, in a surface of the insulating substrate, wherein when a fine wire portion and a wide-width wire are mixed, the depth of the concave portions is formed so that the wide-width portion is thinner, and a first metal layer, which is a barrier layer, and a second metal layer, which is wiring, are provided in the concave portions.

An embodiment of the present invention will be described below with reference to the accompanying drawings. However, it should be noted that this embodiment is only one example for implementing the present invention and does not limit the technical range of the present invention. Also, in the figures, the same reference numerals denote common components.

### <Configuration of Copper Wiring Board>

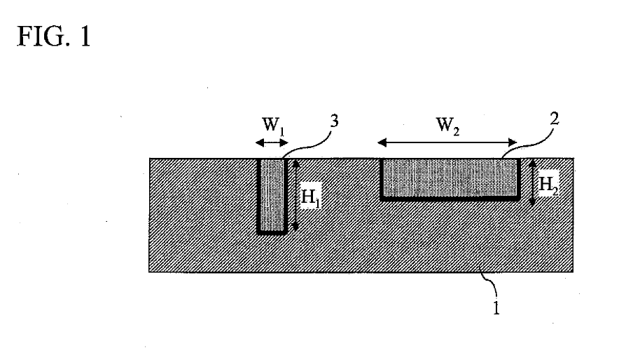

FIG. 1 is a schematic view showing the configuration of a copper wiring board in an embodiment of the present invention. Concave portions, which form a wiring pattern, are formed in an insulating substrate 1. The concave portions can be formed in any shape, such as a trench shape and a hole shape, so as to be the shape of wires. The width of the concave portions is not particularly limited, but can be 0.1 μm to 1 mm. Particularly, the range of 1 to 100 μm is preferred because processing is easy. The interval between the concave portions is not particularly limited, but can be 0.1 μm to 1 mm. Particularly, the range of 1 to 100 μm is preferred because processing is easy. The concave portions and the interval between the concave portions can also be with various widths and shapes or combinations thereof. When a wide-width wire 2 and a narrow-width wire 3 having different wire widths are formed, it is essential to form the depth of the previously formed concave portions so that the wide-width wire is thinner.

The insulating substrate 1 is not particularly limited, but, for example, ceramic materials, such as glass, alumina, aluminum nitride, and silicon carbide, and resin materials, such as PPS (polyphenylene sulfide), PEEK (polyetheretherketone), polyphthalamide, PET (polyethylene terephthalate), PTFE (Polytetrafluoroethylene), an acrylic resin, polycarbonate, polystyrene, polycyclooxide, an epoxy resin, polyimide, and LCP (a liquid crystal polyester resin), can be used. Particularly, epoxy resins and polyimide resins having excellent electrical properties are preferably used. In a preform formed in this step, at least a surface on which a circuit is formed should be formed of an insulating material. A preform, such as a metal core substrate in which the surface of copper, aluminum, or the like is covered with an insulating material, can also be used. The form of these insulating materials may be any of a film, a glass cloth-laminated sheet, a copper-clad sheet, and the like, and a form in which a liquid varnish is applied to a carrier film or the like is also possible.

### <Method for Manufacturing Copper Wiring Board>

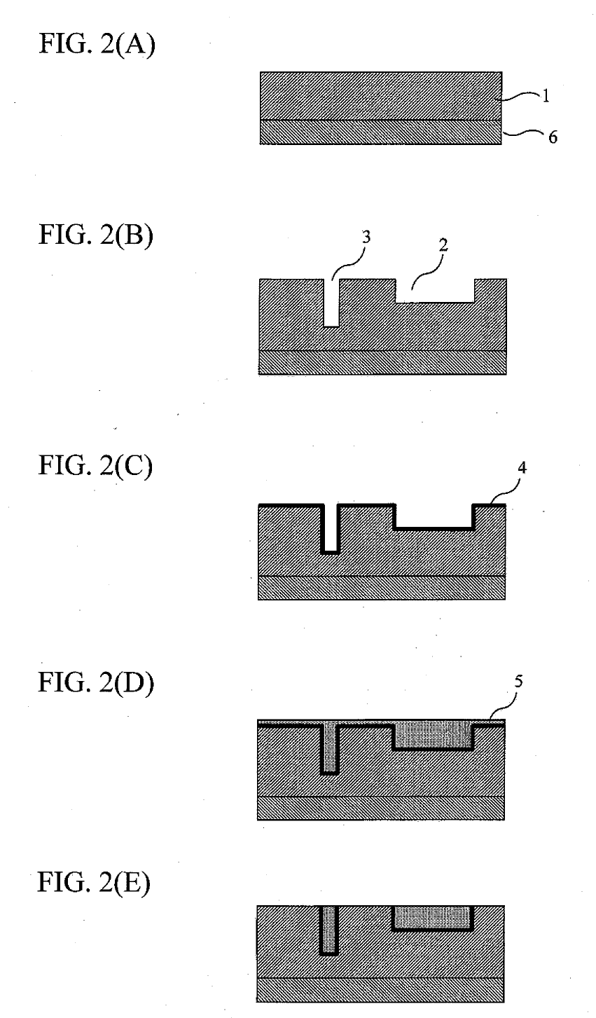

Next, a method for manufacturing a copper wiring board according to the present invention will be described. FIGS. 2(A) to 2(E) show a process for manufacturing a copper wiring board according to the present invention. FIGS. 2(A) to 2(E) show cross sections of the wiring board in the main steps of the manufacturing method, in order of the steps. In the method for manufacturing a copper wiring board according to the present invention, concave portions 2 and 3, which are wire trenches, are formed in a surface of the insulating substrate 1 (FIG. 2(A)) (FIG. 2(B)), a base metal layer 4 is formed on the concave portions 2 and 3 (FIG. 2(C)), and further, a copper plating film 5, which is wiring, is formed on the base metal layer 4 (FIG. 2(D)). Then, a wiring layer is formed by removing the metal layers formed on the surface other than the concave portions (FIG. 2(E)). Detail description will be given below.

### (Wire Shape)

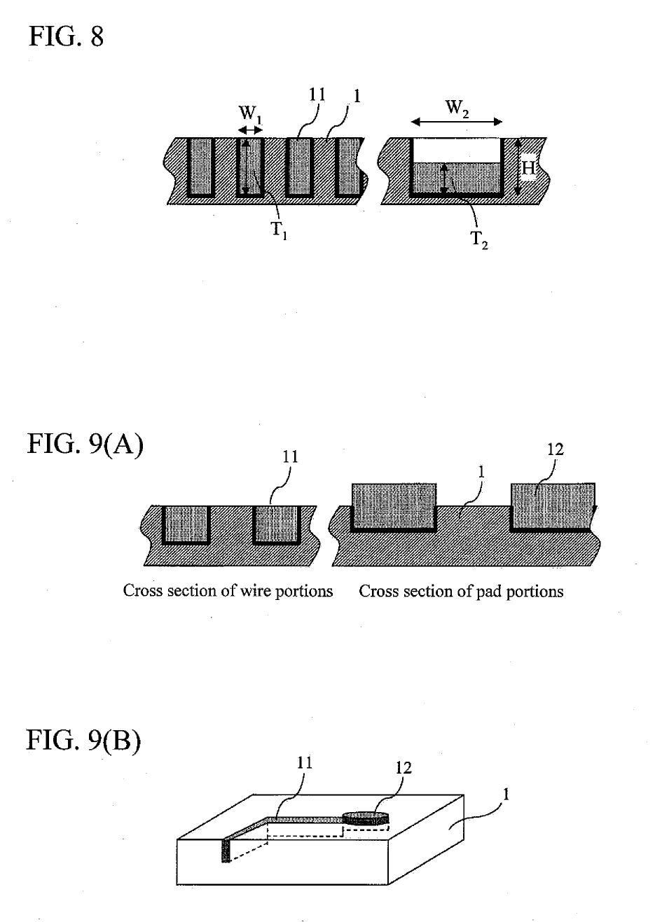

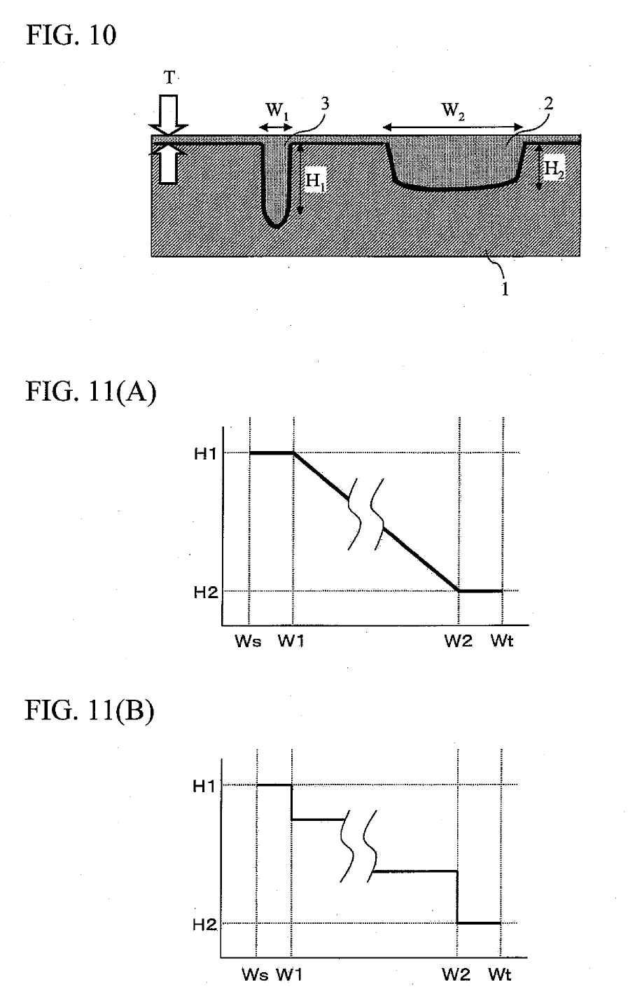

As shown in FIG. 2(B), the concave portions are formed so that their depths are different depending on the width of the wires. Such an insulating substrate having different depths can also be manufactured by forming insulating films having different thicknesses on an insulating substrate so that the bottom surfaces of wires match, but it is easier to process trenches so that the upper surfaces of wires match. Also, the gauge of one wire need not be uniform. For example, the gauge may increase continuously or stepwise from a narrow-width wire to a wide-width wire. In this case, the depth of the trench should be continuously or stepwise decreased depending on the gauge of the wire. Here, the depth of the trench is preferably designed from a filling rate (the ratio of the deposition height of copper plating to the depth of a formed trench) for one or more reference wire widths. For example, when using a substrate in which, with two wire widths (W1 and W2) selected, trenches having the same depth (H) are formed, as shown in FIG. 8, and with a copper plating solution and conditions used for the manufacture of a wiring board, the filling of the trench by electroplating for the narrow-width wire (W1) is previously completed, that is, the filling rate is 1 (=T1/H), a filling rate for a wide-width wire X=(T2/H) is measured. Then, when the depth of the narrow-width trench and wide-width trench of the wiring board is designed as H1 and H2=X·H1, respectively, as shown in FIG. 1, the upper surfaces of the wires can be uniform.

### (Formation of Wire Trenches)

To form the concave portions as shown in FIG. 2(B), for example, wire trenches can be formed by manufacturing a die having convex portions having different heights, and transferring a replica pattern to an insulating film. In the die, unevenness may be formed in a flat substrate surface, or, for example, the die may be formed in a roll shape. A roll-shaped die can continuously transfer a pattern and is preferred. The wire trenches can also be formed by a laser or photolithography using a publicly known photoresist, other than the die.

Also, a pad trench for a pad for mounting an electronic device can be formed in part of a copper wire. The pad is desirably formed convexly from the upper surface of the copper wire. In this case, the pad can be formed by performing the plating of the present invention on a substrate having concave portions in which the depth of the pad is shallower than the depth of the copper wire portion. A blind via for connection to a lower wiring layer can also be formed simultaneously with the formation of wire trenches.

### (Formation of First Metal Layer)

The first metal layer 4 formed on the concave portions, which is a seed layer for copper plating deposition in post-treatment, as shown in FIG. 2(c), can be formed by a dry method, such as sputtering, a wet method, such as electroless plating, or an application method, such as a sol-gel method. A wet method, which requires low cost, is preferred, and electroless plating is more preferred. In the case of electroless plating, copper, nickel alloys, such as nickel-phosphorus, nickel-phosphorus-boron, nickel-boron, nickel-tin-phosphorus, nickel-iron-phosphorus, nickel-zinc-phosphorus, nickel-tungsten-phosphorus, and nickel-molybdenum-phosphorus, cobalt alloys, such as cobalt-phosphorus and cobalt-boron, copper alloys, such as copper-tin and copper-zinc, silver, silver alloys, such as tin-silver, or mixtures thereof can be used for plating. Also, when tungsten, molybdenum, or the like, which is a high melting point metal, is added to an electroless plating film of nickel-phosphorus, nickel-boron, cobalt-phosphorus, cobalt-boron, or the like, the electroless plating film functions as a barrier film for inhibiting the diffusion of copper used as the wiring material, thus, leading to an improvement in the reliability of the wiring, and such addition is preferred. Also, nickel-boron also has excellent adhesion between the insulating substrate and the wiring material, and is therefore more preferred.

The thickness of the first metal layer is not particularly limited, but is preferably 0.01 μm to 5 μm, more preferably 0.05 μm to 2 μm. If the thickness of this metal layer is less than 0.01 μm, the resistance of the metal layer is high, and the metal layer does not function as a seed when copper plating is performed. On the contrary, if a thick metal layer is deposited, of course, the deposition time is long, the manufacturing cost is high, and moreover, removal between the wires is difficult. Therefore, the thickness is desirably 5 μm or less.

### (Formation of Second Metal Layer)

As a method for forming the copper plating film 5 on the insulating substrate having concave portions in a surface, as shown in FIG. 2(D), a publicly known copper plating solution can be used. Further, when the copper plating solution comprises an additive that can suppress deposition on portions, other than the concave portions, to a minimum, the step of removing the extra plating film can be simplified, and therefore, such an additive is preferred. A plating method most preferred for the present invention will be described below, but this is not limiting.

The feature of the plating method of the present invention is that copper electroplating is preferentially performed in the concave portions, using an additive for inhibiting plating reaction. Substantially selective plating can be deposited only in the concave portions by this method. In other words, the thickness of the plating film in the concave portions can be made sufficiently thicker than the thickness of the plating film on the substrate surface portion other than the concave portions, and therefore, the copper plating film on the substrate surface other than the concave portions can be easily removed.

### (Plating Solution)

As the solution used for copper plating, a plating solution comprising copper ions, sulfuric acid, and chlorine ions, to which the above-described additive and a surfactant are added, is used. The above plating solution can be preferably used by adding hydrochloric acid to an acidic aqueous solution of sulfuric acid, in which copper sulfate pentahydrate is dissolved, to make the plating solution. Also, the plating solution may comprise bis(3-sulfopropyl)disulfide, which is a publicly known promoter, polyethylene glycol as a surfactant, and the like, other than the above components.

A substance that inhibits plating reaction, and loses the effect of inhibiting plating reaction, simultaneously with the progress of plating reaction, is good as the additive for a reason described later. The effect that the additive inhibits plating reaction can be confirmed by the fact that the deposition overvoltage of metal increases by adding the additive into the plating solution. On the other hand, the effect that the additive loses the effect of inhibiting plating reaction, simultaneously with the progress of the plating reaction, can be confirmed by the fact that as the flow rate of the plating solution increases, the deposition overvoltage of plating metal increases. This indicates that as the speed of supplying the additive to the first metal layer surface increases, the effect of inhibiting plating reaction increases. When the additive loses the effect of inhibiting plating reaction, the additive may be decomposed and changed to another substance, or may be reduced and changed to a substance having a different oxidation number.

The reason why plating can be substantially selectively deposited in the concave portions by performing plating with a plating solution comprising such an additive will be described below. When plating is performed using such an additive, the additive loses its effect on the first metal layer surface, with the progress of plating reaction. As a result, the effective additive concentration involved in the plating reaction on the first metal layer surface decreases. When the concentration of the additive decreases, the additive is supplied by diffusion from the solution, but in the concave portions, the distance from the offing of the plating solution (a place where plating is supplied) is longer than that on the substrate surface. Therefore, in the concave portions, the supply of the additive is slow, and the speed of increase in additive concentration due to the diffusion is slow. Therefore, a state in which the additive concentration in the concave portions is lower than that on the substrate surface is maintained. Since this additive has the effect of inhibiting plating reaction, plating reaction is not inhibited in the concave portions where the additive concentration is low, and a plating film can grow selectively in the concave portions.

The plating solution having such properties preferably has the property of having, in a polarization curve obtained by measurement with a rotating disk electrode, a potential region in which the current value when the electrode rotates at 1000 rpm is 1/100 or less of that when the electrode is stationary. In such a plating solution, at certain potential E′, a current density B at 1000 rpm is 1/100 or less of a current density A when the electrode is stationary (0 rpm), as shown in FIG. 6.

The additive that can be preferably used as the additive for the plating solution desirably comprises at least one of cyanine dyes, such as 2-[(1,3-dihydro-1,3,3-trimethyl-2H-indol-2-ylidene)-methyl]-1,3,3-trimethyl-3H-indolium perchlorate, 2-[3-(1,3-dihydro-1,3,3-trimethyl-2H-indol-2-ylidene)-1-propenyl]-1,3,3-trimethyl-3H-indolium chloride, 2-[5-(1,3-dihydro-1,3,3-trimethyl-2H-indol-2-ylidene)-1,3-pentadienyl]-1,3,3-trimethyl-3H-indolium iodide, 2-[7-(1,3-dihydro-1,3,3-trimethyl-2H-indol-2-ylidene)-1,3,5-heptatrienyl]-1,3,3-trimethyl-3H-indolium iodide, 3-ethyl-2-[5-(3-ethyl-2(3H)-benzothiazolylidene)-1,3-pentadienyl]benzothiazolium iodide, and Janus Green B, and derivatives thereof.

### (Removal of Metal Layer)

As shown in FIG. 2(E), a wiring layer is formed by removing the metal layers formed on the surface other than the concave portions. Thus, a wiring board in which the copper plating film 5, which is wiring, is embedded in the insulating substrate 1 can be manufactured.

### (Conclusion)

In this embodiment, it is possible to separate the wires with good insulation by forming the concave portions in the substrate and forming the wires in the concave portions. Also, it is possible to make the surfaces of the narrow-width portion and the wide-width portion uniform by making the depth of the concave portions different. Therefore, it is possible to form a copper circuit having high-density wiring, without impairing reliability between wires, and provide a fine copper wiring board. Also, the surfaces of the wires are uniform, even in the wide-width portion, and therefore, the wiring board is suited for multilayering. Further, the feature of the wiring board in the present invention is that the adhesion between the wires and the insulating substrate is good because the wiring board has the wires in the concave portions.

### Example 1

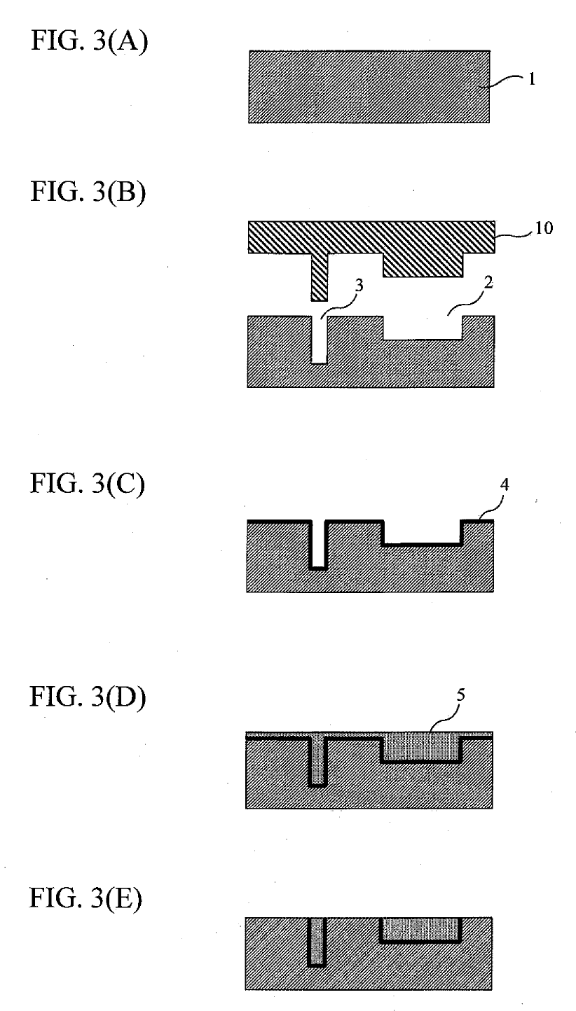

A process for manufacturing a copper wiring board according to the present invention is shown in FIGS. 3(A) to 3(E). This Example is characterized in that wire trenches were formed using a die.

First, wiring-patterned, concave trenches were formed in a surface of an insulating substrate 1, as shown in FIG. 3(B). A glass-epoxy substrate was used for the insulating substrate 1. A 25 μm build-up resin film (Ajinomoto Fine-Techno Co., Inc., ABF-GX) was placed on the glass-epoxy substrate, and then, they were hot press-bonded by a Ni die. When the die was released after cooling, a wiring-patterned replica was transferred. One of the formed wire trenches had a narrow width of 10 μm and a depth of 12 μm, and the other had a wide width of 100 μm and a depth of 7 μm. The narrow-width trench had an aspect ratio (depth/width) of 1.2, and the wide-width trench had an aspect ratio of 0.07.

Next, a first metal layer 4 was formed by electroless nickel plating, as shown in FIG. 3(C). In the electroless nickel plating, Top Chem Alloy 66 manufactured by Okuno Chemical Industries Co., Ltd. was used, and the nickel film thickness was 200 nm. As the method for forming the base film, vapor deposition, sputtering, chemical vapor deposition (CVD), and the like can be used. As the first metal layer 4, nickel, chromium, tungsten, palladium, titanium, and alloys thereof can be used.

Then, a copper plating film 5 was formed by copper electroplating, as shown in FIG. 3(D). In the electroplating, 10 ppm of 2-[(1,3-dihydro-1,3,3-trimethyl-2H-indol-2-ylidene)-methyl]-1,3,3-trimethyl-3H-indolium perchlorate, 50 ppm of chlorine ions, and 100 ppm of polyethylene glycol were added as additives to a plating solution shown in Table 1 for use.

TABLE 1

| Component | Concentration (g/dm³) |
|---|---|
| Copper sulfate | 150 |
| pentahydrate | |
| Sulfuric acid | 180 |

For the plating conditions, the plating time was 15 minutes, the current density was 1.0 A/dm², and the temperature of the plating solution was 25° C.

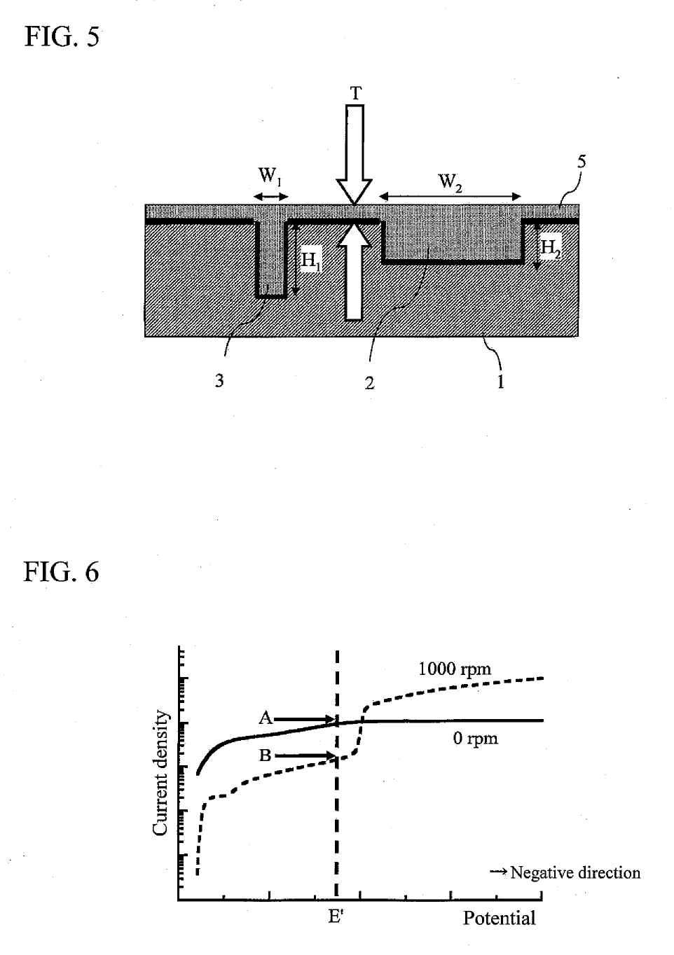

After the copper electroplating, wire cross sections were observed. As shown in FIG. 5, copper plating film thickness H in the wire trenches and copper plating film thickness T on a surface other than the wires were measured. As a result, the copper plating film thickness H1 inside the 10 μm wide wire trench was 12 μm, the copper plating film thickness H2 inside the 100 μm wide wire trench was 7 μm, and the copper plating film thickness T on the surface was 0.1 μm or less. From this, it was found that when wire trenches are processed using a die, a copper plating film grow selectively into the trenches, and form a uniform surface shape, regardless of the wire width. Further, it was found that by using the plating solution in this Example, copper is hardly deposited on the surface other than the trenches.

Next, the copper and nickel films on the surface were removed, as shown in FIG. 3(E). For the removal of the nickel film, CH-1935 manufactured by MEC COMPANY CO., LTD. was used. For the removal of the nickel film, Melstrip manufactured by Meltex Inc., SEEDLON process manufactured by EBARA-UDYLITE CO., LTD., and the like can be used. The copper plating film on the surface was simultaneously removed with the nickel film.

From the above, when the copper plating solution of the present invention was used, the process for removing the copper plating film on the surface was unnecessary, and the manufacture of the wiring board in which the narrow-width and the wide-width copper wires were mixed was easy. Further, the wires were embedded in the insulating substrate, and therefore, fine wiring was formed without the copper wires coming off.

### Example 2

This Example is characterized in that wire trenches were formed using a laser.

First, wiring-patterned, concave trenches were formed in a surface of an insulating substrate 1. A glass-epoxy substrate was used for the insulating substrate 1. A 25 μm build-up resin film (Ajinomoto Fine-Techno Co., Inc., ABF-GX) was thermocompression bonded onto the glass-epoxy substrate, and a different-width wire trench pattern was processed in the surface, using an excimer laser. The trench widths and the trench depths were similar to those in Example 1, by adjusting the laser output intensity and the pulse shot number. Since it was preferable to perform a desmearing step after the laser processing, treatment was performed with MLB495 manufactured by Meltex Inc. in this Example.

Next, a first metal layer 4 was formed by electroless nickel plating, and then, a copper plating film 5 was formed by copper electroplating, as in Example 1.

As a result of observing wire cross sections after the copper electroplating, non-flat trench bottoms were formed due to the effect of the laser processing, as shown in FIG. 3(D). The copper plating film thickness inside the 10 μm wide wire trench was 12 μm, the copper plating film thickness inside the 100 μm wide wire trench was 6.8 μm, and the copper plating film thickness T on the surface was 0.5 μm or less. In this Example, the desmearing step was performed, and therefore, roughness in the convex portion surface was large, and deposition on the surface also occurred. From this, it was found that when wire trenches are processed by a laser, a copper plating film grow preferentially into the trenches. Also, it was found that although the precision of the trench depth and the rectangularity of the processed shape are poor, a photomask, a die, and the like are unnecessary, pattern change and the like were easy, and the productivity is high.

Then, the copper and nickel films on the surface were removed, as in Example 1. Although the removal of the copper plating film on the surface was necessary, unlike Example 1, the copper film was thin, and therefore, the removal was easy.

From the above, the manufacture of the board in which the narrow-width and the wide-width copper wires were mixed was easy. Further, the wires were embedded in the insulating substrate, and therefore, fine wiring was formed without the copper wires coming off.

### Example 3

This Example is characterized in that wire trenches were formed using sputtering.

First, wiring-patterned, concave trenches were formed in a surface of an insulating substrate 1, as shown in FIG. 3(B). A glass-epoxy substrate was used for the insulating substrate 1. A 25 μm build-up resin film (Ajinomoto Fine-Techno Co., Inc., ABF-GX) was placed on the glass-epoxy substrate, and then, they were hot press-bonded by a Ni die to process wire trenches and the like.

Next, as a first metal layer, a nickel film containing 25% chromium and having a film thickness of 100 nm, was formed using sputtering, and a copper plating film 5 was formed by copper electroplating.

As a result of observing wire cross sections after the copper electroplating, the copper plating film thickness inside the 10 μm wide wire trench was 12 μm, the copper plating film thickness inside the 100 μm wide wire trench was 7 μm, and the copper plating film thickness T on the surface was 0.3 μm or less. From this, it was found that when wire trenches are formed using sputtering, a copper plating film grow selectively into the trenches, and form a uniform surface shape, regardless of the wire width. Then, the copper and nickel films on the surface were removed, as in Example 1.

In the etching of the first metal layer in this Example, treatment similar to that in Example 1 was performed, but 20% etching residues were present in the plane, and double treatment time was required. Therefore, the copper plating film at the upper surfaces of the wires, after the etching, had a rough surface shape, but the manufacture of the wiring board in which the narrow-width and the wide-width copper wires were mixed was easy. Further, the wires were embedded in the insulating substrate, and therefore, fine wiring was formed without the copper wires coming off.

### Example 4

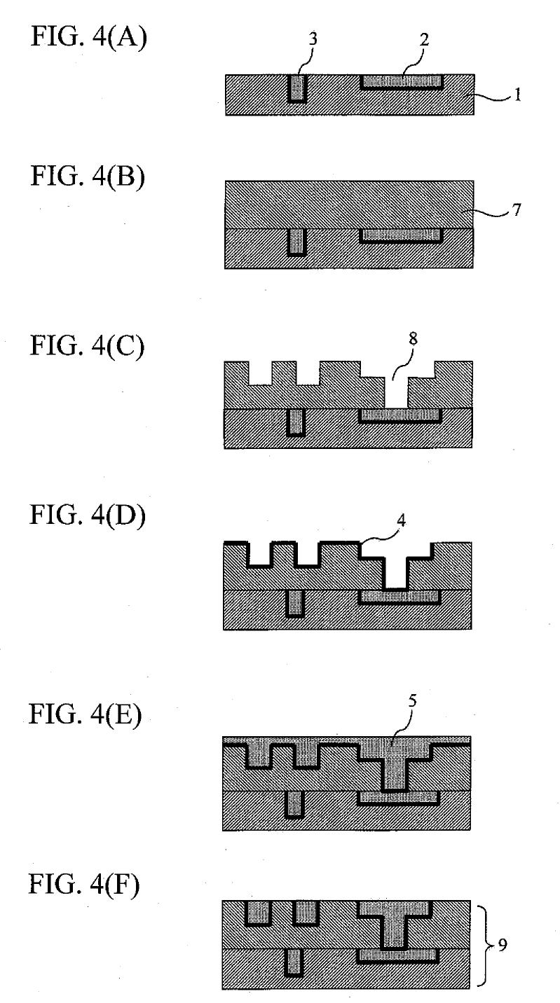

This Example is characterized in that a multilayered wiring board was formed, and interlayer connection vias were formed. A process for manufacturing a copper wiring board according to the present invention is shown in FIGS. 4(A) to 4(F). FIGS. 4(A) to 4(F) are cross-sectional views of the board, showing a method for forming interlayer connection vias according to the present invention.

First, wiring-patterned, concave trenches were formed in a surface of an insulating substrate 1, as shown in FIG. 4(A). A glass-epoxy substrate was used for the insulating substrate 1. A 25 μm build-up resin film (Ajinomoto Fine-Techno Co., Inc., ABF-GX) was placed on the glass-epoxy substrate, and then, they were hot press-bonded by a Ni die to form interlayer connection vias to the lower layer, and wire trenches, as shown in FIG. 4(C). The interlayer connection vias had φ 10 to 80 μm and a depth of 10 μm. For ensuring wire connection at via bottoms, it was effective to pierce the insulating layer by sharpening the tips on the die side, and to clean the resin residues by desmearing.

Then, a metal layer 4 was formed by electroless plating, and a copper plating film 5 was formed by copper electroplating, as in Example 1.

As a result of observing wire cross sections after the copper electroplating, the copper plating film thickness inside the 10 μm wide wire trench was 12 μm, the copper plating film thickness inside the 100 μm wide wire trench was 7 μm, and the copper plating film thickness T on the surface was 0.1 μm or less. From this, it was found that when multilayered wiring and interlayer connection vias are formed using a die, a copper plating film grow selectively into the resist openings and is hardly deposited on the insulating film surface.

Next, the copper and nickel films on the second insulating film surface were removed, as shown in FIG. 4(F). The copper plating film on the surface was simultaneously removed with the nickel film, as in Example 1.

From the above, the process for removing the copper plating film on the resist surface was unnecessary, and the manufacture of the wiring board having interlayer connection vias having a diameter of 10 to 80 μm were mixed was easy.

### Example 5

This Example is characterized in that a board having various wire widths was formed.

First, wire trenches were formed by a method similar to that in Example 1, changing the width to increase from 5 μm to 200 μm in increments of 5 μm. To set trench depth for each wire width when the wire widths are different, wire trenches having the same depth and different widths are formed in a previously separately prepared substrate, and the ratio of the filling rate for wire widths when copper plating is provided on the substrate is examined. This time, in the separately fabricated substrate, the filling rate for a width of 100 μm was 0.65 when the filling rate of the trench for a width of 20 μm was 1. Therefore, the trench depth in this Example was calculated as 10 μm for widths of 5 to 20 μm, 8 μm for widths of 25 to 50 μm, and 6.5 μm for widths of 100 to 200 μm, and trenches were formed in such a manner, using a die. In this Example, the trenches were formed at trench depths such that the filling rate for wires having widths of 20 μm and 100 μm was 1 at the same time, and at a fixed depth for wires having other widths. But, any design is possible, for example, so that wires equal to or narrower than a reference narrow-width wire are thicker, wide-width wires equal to or wider than a reference wide-width are thinner, and the depth is also middle for a middle-width wire.

Next, a metal layer 4 was formed by electroless plating, and a copper plating film 5 was formed by copper electroplating, as in Example 1.

As a result of observing wire cross sections after the copper electroplating, the copper plating film thickness inside the 20 μm wide wire trench was 10 μm, the copper plating film thickness inside the 100 μm wide wire trench was 6.5 μm, and the copper plating film thickness T on the surface was 0.1 μm or less. Also, in other wire portions, the filling rate was 0.85 or more, and it was found that the occurrence of unevenness in the upper surface of the substrate can be inhibited regardless of the wire width, and a uniform substrate surface can be formed.

Then, the copper and nickel films on the surface were removed, as in Example 1. The copper plating film on the surface was simultaneously removed with the nickel film, as in Example 1.

From the above, the manufacture of the wiring board in which the copper wires having various gauges were mixed was easy. Further, the wires were embedded in the insulating substrate, and therefore, fine wiring was formed without the copper wires coming off.

### Example 6

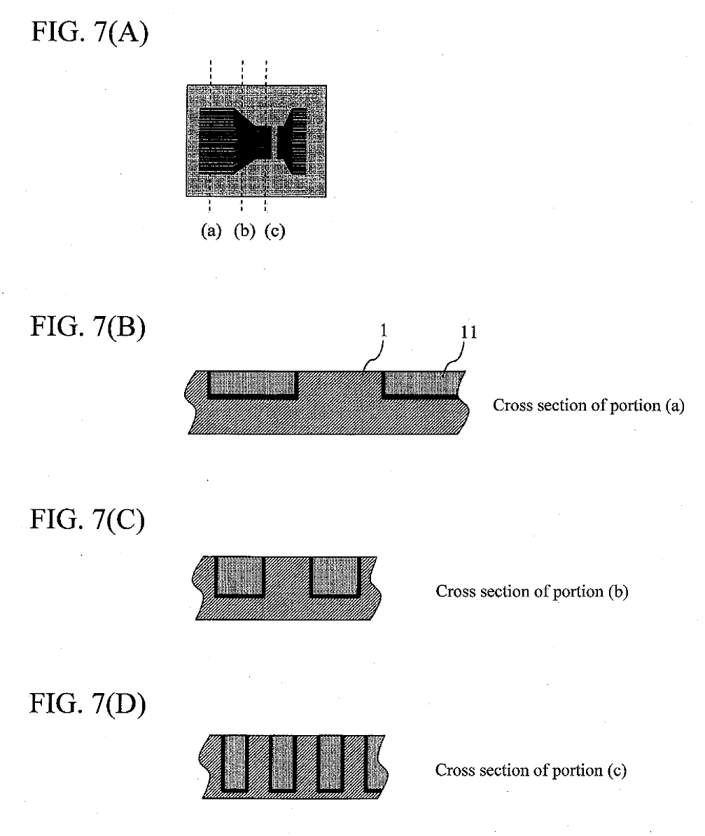

This Example is characterized in that the gauge of one wire changed. A process for manufacturing a copper wiring board according to the present invention is shown in FIGS. 7(A) to 7(D).

In this Example, a wire trench pattern was formed so that the width was 100 μm in a portion (a), 50 μm in a portion (b), and 10 μm in a portion (c), as shown in FIGS. 7(A) to 7(D). Also, the depth of the wire trenches was 6.5 μm in the portion (a), 7.8 μm in the portion (b), and 10 μm in the portion (c). In designing the depth of the trenches, it is preferably designed from a filling rate (the ratio of the deposition height of copper plating to the depth of a formed trench) for one or more reference wire widths. For example, when using a substrate in which, with two wire widths (W1 and W2) selected, trenches having the same depth are formed, as shown in FIG. 8, and with a copper plating solution and conditions used for the manufacture of a wiring board, the filling of the trench by electroplating for the narrow-width wire W1 is previously completed, that is, the filling rate is 1, a filling rate X for a wide-width wire W2 is measured. When the depth of the narrow-width trench and wide-width trench of the wiring board is H1 and X·H1, respectively, the upper surfaces of the wires can be uniform. In this Example, copper plating was performed under conditions similar to those of Example 1 on a substrate in which 10 μm trenches were formed with W1 being 10 μm and W2 being 100 μm. As a result, the filling rate for W2 was 0.65, and therefore, the depth in the portion (a) with wide width was 6.5 μm. Also, in the portion (b), the filling rate was linearly approximated to wire width, and the depth was 7.8 μm.

Next, a metal layer 4 was formed by electroless plating, and a copper plating film 5 was formed by copper electroplating, as in Example 1. As a result of observing wire cross sections after the copper electroplating, the copper plating fills to the surface in the portion (a), the portion (b), and the portion (c), and the copper plating film thickness on the surface was 0.1 μm or less. Then, the copper and nickel films on the surface were removed, as in Example 1. The copper plating film on the surface was simultaneously removed with the nickel film, as in Example 1.

From the above, also when the wire width changed in the same wire, the occurrence of unevenness in the upper surface of the substrate was inhibited, and the manufacture of the wiring board in which the copper wires having various gauges were mixed was easy.

In this Example, the wire width changed stepwise, but, for example, the wire width may increase continuously or stepwise from a narrow-width wire to a wide-width wire. In this case, the depth of the trench may be continuously or stepwise decreased depending on the gauge of the wire, as shown in FIG. 11 (A). Thus, the flatness of the surface can be ensured.

Also, as shown in FIG. 11 (B), when the relationship between a narrowest wire trench width Ws and the wire width W1 for which the filling rate is measured in the test substrate is Ws≦W1, a wire trench depth Hs for the wire trench width Ws can be Hs=H1. Thus, the complicatedness of processing can be reduced. Further, when the relationship between a widest wire trench width Wt and the wire trench width W2 for which the filling rate is measured in the test substrate is Wt≧W2, a wire trench depth Ht for the wire trench width Wt can be Ht=X·H1, and the complicatedness of trench processing can be reduced.

### Example 7

This Example is characterized in that pads for mounting electronic components were formed in the same plane as wires.

As shown in FIGS. 9(A) and 9(B), wire trenches and circular pad trenches were formed by a method similar to that in Example 1. The wire trenches were formed with widths of 10 μm and 100 μm, and wire depths of 10 μm and 6.5 μm, respectively. The pad trenches had φ 250 μm and a depth of 3 μm.

Next, a metal layer 4 was formed by electroless plating, and a copper plating film 5 was formed by copper electroplating, as in Example 1.

As a result of observing wire cross sections after the copper electroplating, it was found that the wire portions were filled with copper plating to the surface, and the pads were 2.5 μm convex in the upper portion. The copper plating film thickness on the insulating film surface was 0.1 μm or less.

Then, the copper and nickel films on the surface were removed, as in Example 1. The copper plating film on the surface was simultaneously removed with the nickel film, as in Example 1.

Finally, a publicly known solder resist was applied, electroless nickel plating and gold plating were provided on the open pads, and then, electronic components were mounted by solder.

From the above, in this Example, in the pads, a convex shape was easily formed, and the electronic components were easily mounted.

### Example 8

This Example is characterized in that a different copper plating solution was used.

Using a publicly known copper electroplating solution for via filling (manufactured by EBARA-UDYLITE CO., LTD., CU-BRITE VF4), copper plating was provided on a substrate having wire trenches formed as in Example 1. The sample was taken out during plating, and a cross section was observed. As a result, the copper plating film thickness inside the 10 μm wide wire trench was 10 μm, the copper plating film thickness inside the 100 μm wide wire trench was 4.5 μm, and the copper plating film thickness T on the surface was 2.5 μm. From this, it was found that when a copper electroplating solution for via filling is used, a copper plating film grow preferentially into the trenches, but is also deposited on the surface.

Then, in this Example, copper plating was provided for a long plating time so that the wide-width portion could also be sufficiently filled. As a result of observing a cross section, the copper plating film thickness inside the 10 μm wide wire trench was 17 μm, the copper plating film thickness inside the 100 μm wide wire trench was 12 μm, and the copper plating film thickness T on the surface was 7 μm. The entire surface was completely covered with the copper plating film, but unevenness was inhibited in the wire portions and other portions.

Then, when etching was performed with a solution of 100 g/dm³ sodium persulfate to remove the copper on the surface, the nickel film was removed simultaneously with the copper on the surface.

From the above, in this Example, the copper in the wire portions was also etched when the copper deposited on the insulating film surface was removed, and therefore, the film thickness of the copper wires after the etching decreased such that the copper plating film thickness inside the 10 μm wide wire trench was 11 μm, and the copper plating film thickness inside the 100 μm wide wire trench was 6 μm. But, the manufacture of the wiring board in which the narrow-width and the wide-width copper wires were mixed was easy. Further, the wires were embedded in the insulating substrate, and therefore, fine wiring was formed without the copper wires coming off.

### Example 9

This Example is characterized in that a film substrate was used as the insulating substrate.

A thermoplastic polyimide film (Kapton manufactured by DU PONT-TORAY CO., LTD.), polyetherimide (SUPERIO-UT manufactured by Mitsubishi Plastics, Inc.), polyethylene terephthalate (Teflex manufactured by Teijin DuPont Films Japan Limited), and a liquid crystal polymer (BIAC manufactured by Japan Gore-Tex Inc.) were used as substrates, and wire trenches were formed in each substrate, as in Example 1.

As a result of observing wire cross sections after the copper electroplating, when any substrate was used, the filling rate of the trenches was 0.9 or more for both of a width of 10 μm and a width of 100 μm, and the copper plating film thickness T on the surface was 0.1 μm or less. From this, it was found that when a film substrate is used as the insulating substrate, a copper plating film grow selectively into the trenches, and form a uniform surface shape, regardless of the wire width.

Then, wiring boards were manufactured by removing the copper and nickel films on the surface, as in Example 1.

From the above, in this Example, the manufacture of the wiring board in which the narrow-width and the wide-width copper wires were mixed was easy. Further, the wires were embedded in the insulating substrate, and therefore, the wires were not affected by the insulating material, and fine wiring was formed, without the copper wires coming off, for any substrate.

### Example 10

This Example is characterized in that a varnish-like resin was used as the insulating substrate.

Each of polyimide (U-Varnish manufactured by Ube Industries, Ltd.), a solder resist (TF-200 manufactured by TAIYO INK MFG. CO., LTD.), a solder resist (PSR-4000 manufactured by TAIYO INK MFG. CO., LTD.), and a solder resist (SN-9000 manufactured by Hitachi Chemical Co., Ltd.), which were publicly known insulating material resins, was applied, with a thickness of 25 μm, onto a glass-epoxy substrate, then, compression bonded to a Ni die, and cured to form wire trenches. Due to the effect of gasification of the solvent in the curing of the resin, small voids were formed in the surface, but a good trench shape was formed.

As a result of observing wire cross sections after the copper electroplating, when any substrate was used, the filling rate of the trenches was 0.9 or more for both of a width of 10 μm and a width of 100 μm, and the copper plating film thickness T on the surface was 0.1 μm or less. From this, it was found that when a varnish-like resin is used as the insulating substrate, a copper plating film grow selectively into the trenches, and form a uniform surface shape, regardless of the wire width.

Then, wiring boards were manufactured by removing the copper and nickel films on the surface, as in Example 1.

From the above, in this Example, the manufacture of the wiring board in which the narrow-width and the wide-width copper wires were mixed was easy. Further, the wires were embedded in the insulating substrate, and therefore, the wires were not affected by the insulating material, and fine wiring was formed, without the copper wires coming off, for any substrate.

### Example 11

Reliability was evaluated using wiring boards formed as in Examples 1 to 10 except Example 4 (multilayered wiring and interlayer via formation). For wiring evaluation, a comb teeth pattern was used, and the wire width was such that the line/space was 10/10 μm in the narrow-width portion, and 100/100 μm in the wide-width portion. A solder resist (SN9000 manufactured by Hitachi Chemical Co., Ltd.) was applied to the test substrate having formed fine wiring, and cured under conditions of 150° C. for 90 minutes.

Then, in an environment of 110° C. and 85% RH, a voltage of 60 V was applied, change in wiring resistance over time was measured, and time until the resistance between wires was 10 MΩ or less was measured. As a result, it was found that insulation reliability for target 100 hours or more is obtained in any wiring board, and wiring boards having high reliability can be formed.

### <Others>

Other than the Examples of the present invention, it is also possible to heat and laminate a prepreg and the like, form via holes, an outer layer circuit, and the like, and provide further multilayering by a publicly known insulating layer forming step and a circuit forming step, as required.

Also, it is possible to improve the stability of the wiring surface and improve reliability by applying a solder resist and the like to the surface of the above copper wiring board.

### DESCRIPTION OF SYMBOLS

1: insulating substrate, 2: wide-width wire trench, 3: narrow-width wire trench, 4: first metal layer, 5: copper plating film, 6: second insulating layer, 7: insulating layer, 8: connection via, 9: multilayer wiring board, 10: die, 11: wire, 12: pad

What is claimed is:

1. A wiring board comprising an insulating substrate, a plurality of wire trenches formed in the insulating substrate, and wires filled in the wire trenches,
wherein when any two of the wires are selected, and cross sections are taken perpendicular to a direction of current flow in the wires,
a wire width in one wire cross section is narrower than a wire width in the other wire cross section, and a wire thickness in the one wire cross section is thicker than a wire thickness in the other wire cross section.

2. A wiring board comprising an insulating substrate, a wire trench formed in the insulating substrate, and a wire filled in the wire trench,
wherein when any two points of the wire are selected, and cross sections are taken perpendicular to a direction of current flow in the wire,
a wire width in one wire cross section is narrower than a wire width in the other wire cross section, and a wire thickness in the one wire cross section is thicker than a wire thickness in the other wire cross section.

3. The wiring board according to claim 1, wherein the wires comprise a wire having a ratio of wire thickness to wire width of 1 or more.

4. The wiring board according to claim 1, wherein the wire has a barrier film for inhibiting diffusion of a wire material, formed on a bottom surface and side surfaces.

5. The wiring board according to claim 1, wherein the wires are embedded in an insulating film.

6. The wiring board according to claim 4, wherein the barrier film comprises nickel or cobalt as a main component.

7. The wiring board according to claim 1, comprising an insulating substrate, a plurality of wire trenches formed in the insulating substrate, wires filled in the wire trenches, a pad trench formed in part of the wires, and a pad for mounting an electronic device, filled in the pad trench,
wherein when a cross section is taken perpendicular to a direction of current flow in the wire,
a depth of the pad trench is shallower than the depth of the wire trench in the wire cross section.

8. The wiring board according to claim 7,
wherein when any two of the wires are selected,
a wire width in one wire cross section is narrower than a wire width in the other wire cross section, and a wire thickness in the one wire cross section is thicker than a wire thickness in the other wire cross section.

9. The wiring board according to claim 7, wherein the pad is formed more convexly than the wire with respect to the insulating substrate.

10. A method for manufacturing a wiring board, comprising at least
a step A of molding a plurality of wire trenches in an insulating substrate; and
a step B of filling the formed wire trenches with a first metal layer, which is a base metal film,
wherein in the step A,
the plurality of wire trenches are formed to comprise wires in which, when any two of the wires are selected, and cross sections are taken perpendicular to a direction of current flow in the wires,
a wire width in one wire cross section is narrower than a wire width in the other wire cross section, and a wire thickness in the one wire cross section is thicker than a wire thickness in the other wire cross section.

11. The method for manufacturing a wiring board according to claim 10, further comprising
the step C of forming a second metal layer on a surface of the first metal layer,
wherein at least one of the first metal layer and the second metal layer is copper.

12. The method for manufacturing a wiring board according to claim 11, wherein in the step C, electroplating is performed using a plating solution comprising a substance for increasing deposition overvoltage for metal to be deposited on the surface of the first metal layer.

13. The method for manufacturing a wiring board according to claim 12, wherein in the step C, the plating solution used for forming the second metal layer is an acidic copper sulfate electroplating solution, and the acidic copper sulfate electroplating solution has, in a polarization curve obtained by measurement with a rotating disk electrode rotating at 1000 rpm, a potential region in which a current value, when the electrode rotates, to a current value, when the electrode is stationary, is 1/100 or less.

14. The method for manufacturing a wiring board according to claim 12, wherein in the step C, the plating solution used for forming the second metal layer is an acidic copper sulfate electroplating solution, and the acidic copper sulfate electroplating solution is such that in a polarization curve obtained by measurement with a rotating disk electrode rotating at 1000 rpm, a current value, when the electrode rotates, to a current value, when the electrode is stationary, is 1/100 or less in the range of 100 to 200 mV, and a current value when the electrode rotates is larger than a current value when the electrode is stationary in the range of −100 mV or less, with respect to standard hydrogen electrode potential.

15. The method for manufacturing a wiring board according to claim 13, wherein the acidic copper sulfate electroplating solution comprises at least one of cyanine dye and derivatives thereof.

16. The method for manufacturing a wiring board according to claim 15, wherein the cyanine dye is represented by the following chemical structural formula: 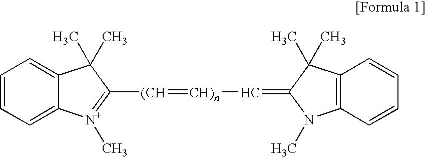
wherein n is any one of 0, 1, 2, and 3.

17. The method for manufacturing a wiring board according to claim 10, wherein the first metal layer is metal or an alloy comprising at least one of nickel, cobalt, chromium, tungsten, palladium, and titanium, and the second metal layer is copper.

18. The method for manufacturing a wiring board according to claim 10,
wherein the step A comprises a step a of previously making a temporary wiring board in which a plurality of temporary wire trenches having the same wire thickness and different wire widths are formed, performing electroplating on the temporary wire trenches, and measuring the filling rate of the electroplating for each of the plurality of temporary wire trenches, and
the wire trenches are formed, based on a wire thickness in the wire cross section determined according to the filling rate of the plurality of temporary wire trenches.

19. The method for manufacturing a wiring board according to claim 18, wherein in the step A the wire trenches are formed to further comprise wires in which the wire thickness of the wire trench having a wire width equal to or less than a reference value, among the plurality of wire trenches, is fixed at a predetermined value.

20. The method for manufacturing a wiring board according to claim 18, wherein in the step A the wire trenches are formed to further comprise wires in which the wire thickness of the wire trench having a wire width equal to or more than a reference value, among the plurality of wire trenches, is fixed at a predetermined value.

21. A method for manufacturing a wiring board, comprising at least
a step A of molding a plurality of wire trenches in an insulating substrate;
a step B of molding a pad trench in part of the wire trenches; and
a step C of filling the formed wire trenches and pad trench with a first metal layer, which is a base metal film,
wherein in the step B,
the pad trench is formed so that when a cross section is taken perpendicular to a direction of current flow in the wire,
a depth of the pad trench is shallower than a wire depth in the wire cross section.
